(19) United States
(12) Patent Application Publication
(10) Pub. No.: US 2007/0249086 A1
(43) Pub. Date: Oct. 25, 2007

(54) Phase change memory

(76) Inventors: Jan Boris Philipp, Peekskill, NY (US); Shoaib Hasan Zaidi, Poughkeepsie, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/407,345

(22) Filed: Apr. 19, 2006

(51) Int. Cl. H01L 29/02; H01L 21/00

(52) U.S. Cl. 438/95; 257/2

(57) ABSTRACT

A memory cell includes a first electrode, a second electrode, a layer of phase change material positioned between the first and second electrodes, and a stress layer contacting the layer of phase change material. The phase change material includes a high temperature state, and the stress layer defines an interface with the phase change material and operates to suppress a transition in the phase change material to the high temperature state.

### BACKGROUND

Semiconductor chips provide memory storage for electronic devices and have become very popular in the electronic products industry. In general, many semiconductor chips are typically formed (or built) on a silicon wafer. The semiconductor chips are individually separated from the wafer for subsequent use as memory in electronic devices. In this regard, the semiconductor chips define an array of memory cells that are configured to store retrievable data, often characterized by the logic values of 0 and 1.

Phase change memory cells are one type of memory cell capable of storing retrievable data between two or more separate states (or phases). In one known structure of a phase change memory cell, the memory cell is formed at the intersection of a phase change memory material and a resistive electrode. Passing energy of an appropriate value through the resistive electrode heats the phase change memory cell, thus affecting a phase/state change in its atomic structure. The phase change memory cell can be selectively switched between logic states 0 and 1, for example, and/or selectively switched between multiple logic states.

Materials that exhibit the above-noted phase change memory characteristics include the elements of Group VI of the periodic table (such as Tellurium and Selenium) and their alloys, referred to as chalcogenides or chalcogenic materials. Other non-chalcogenide materials also exhibit phase change memory characteristics.

The atomic structure of one type of phase change memory cells can be switched between an amorphous state and one or more crystalline states. In this regard, the atomic structure can be switched between a general amorphous state and multiple crystalline states. The amorphous state has greater electrical resistance than the crystalline state(s), and typically includes a disordered atomic structure. In contrast, the crystalline states each generally have a highly ordered atomic structure, and the more ordered the crystalline state, the lower the electrical resistance (and the higher the electrical conductivity).

When switching between memory/phase states the atomic structure of a phase change material becomes highly ordered when maintained at (or slightly above) the crystallization temperature, such that a subsequent slow cooling of the material results in a stable orientation of the atomic structure in the highly ordered (crystalline) state. To switch back to the amorphous state, for example in the chalcogenide material, the local temperature is generally raised above the melting temperature (approximately 600 degrees Celsius) to achieve a highly random atomic structure, and then rapidly cooled to “lock” the atomic structure in the amorphous state.

The temperature-induced changes in phase/state may be achieved in a variety of ways. For example, a laser can be directed to the phase change material, current may be driven through the phase change material, or current can be fed through a resistive heater adjacent the phase change material. In any of these methods, controllable heating of the phase change material causes controllable phase change within the phase change material.

The variation in electrical resistance between the amorphous state and the crystalline state(s) in phase change materials can be beneficially employed in two level or multiple level systems where the resistivity is either a function of the bulk material or a function of the partial material. It is relatively easy to change a chalcogenide between the amorphous state (exhibiting a disordered structure, for example, like a frozen liquid) and the crystalline state(s) (exhibiting a regular atomic structure). In this manner, manipulating the states of the chalcogenide permits a selective control over the electrical properties of the chalcogenide, which is useful in the storage and retrieval of data from the memory cell containing the chalcogenide.

The atomic structure of chalcogenide material can be selectively changed by the application of energy. For chalcogenides such as Ge₂Sb₂Te₅, below temperatures of approximately 150 degrees Celsius both the amorphous and crystalline states are stable. A nucleation of crystals within the chalcogenide can be initiated when temperatures are increased to a low temperature crystallization state (i.e., approximately 175 degrees Celsius). A second high temperature crystallization state is present at approximately 350 degrees Celsius. These crystalline states have different resistivities. As noted above, the more ordered the crystalline state, the lower the electrical resistance, such that the high temperature crystallization state has a lower electrical resistance than even the low temperature crystallization state. Different phase change materials respond to temperature in a similar manner, but with different transition temperatures.

Electronically switching the phase change cell from the high temperature crystalline state back to the amorphous state requires large amount of energy. Thus, a transition in the phase change cell to the high temperature crystalline state is not desirable.

For these and other reasons, there is a need for the present invention.

### SUMMARY

One aspect of the present invention provides a memory cell. The memory cell includes a first electrode, a second electrode, a layer of phase change material positioned between the first and second electrodes, and a stress layer contacting the layer of phase change material. The phase change material includes a high temperature state, and the stress layer defines an interface with the phase change material and operates to suppress a transition in the phase change material to the high temperature state.

### BRIEF DESCRIPTION OF THE DRAWINGS

The accompanying drawings are included to provide a further understanding of the present invention and are incorporated in and comprise a part of this specification. The drawings illustrate embodiments of the present invention and together with the detailed description describe principles of the present invention. Other embodiments of the present invention, and many of the intended advantages of the present invention, will be readily appreciated as they become better understood by reference to the following detailed description. The elements of the drawings are not necessarily to scale relative to each other. Like reference numerals designate corresponding similar parts.

FIG. 1 illustrates a simplified block diagram of a memory device according to one embodiment of the present invention.

FIG. 2 illustrates a cross-sectional view of a phase change memory cell according to one embodiment of the present invention.

FIG. 3 illustrates a schematic drawing of a relationship between electrical resistance and temperature for three states of a layer of phase change material according to one embodiment of the present invention.

FIG. 4 illustrates stress distributions in a stress layer according to embodiments of the present invention.

FIG. 5 illustrates a pillar phase change memory cell according to one embodiment of the present invention.

FIG. 6 illustrates an insulated electrode disposed on a substrate according to one embodiment of the present invention.

FIG. 7 illustrates a layer of phase change material disposed on the electrode illustrated in FIG. 6.

FIG. 8 illustrates a stack including a second electrode disposed on the layer of phase change material illustrated in FIG. 7.

FIG. 9 illustrates a photoresist disposed on the second electrode of the stack illustrated in FIG. 8.

FIG. 10 illustrates the stack of FIG. 9 after an etch and strip process according to one embodiment of the present invention.

FIG. 11 illustrates a stress layer contacting the etched layer of phase change material.

FIG. 12 illustrates the stress layer of FIG. 11 etched back to define two columns of stress layers contacting the layer of phase change material in accordance with the present invention.

FIG. 13 illustrates an insulation layer filled around the stress layers illustrated in FIG. 12 after a planarization process according to one embodiment of the present invention.

FIG. 14 illustrates another pillar phase change memory cell according to one embodiment of the present invention.

### DETAILED DESCRIPTION

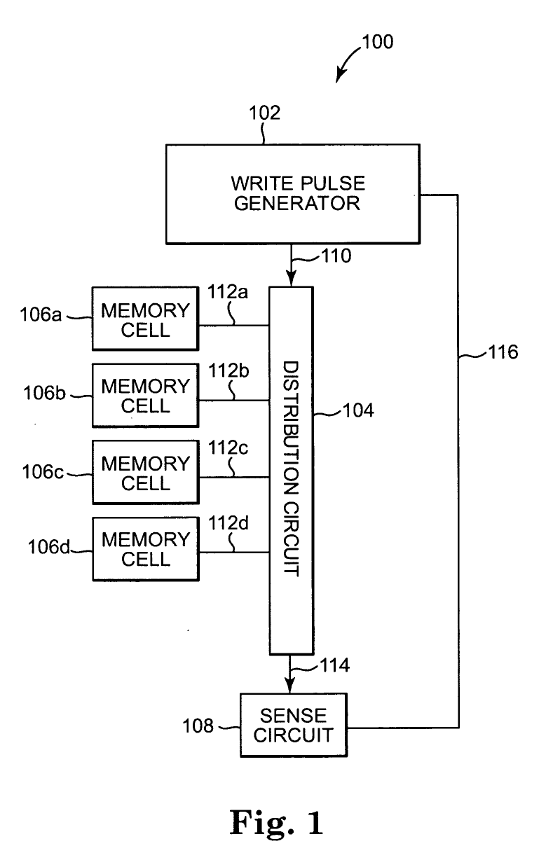

FIG. 1 illustrates a block diagram of a memory device 100 according to one embodiment of the present invention. Memory device 100 includes a write pulse generator 102, a distribution circuit 104, memory cells 106a, 106b, 106c, and 106d, and a sense circuit 108. In one embodiment, memory cells 106a-106d are phase-change memory cells that are based on an amorphous to crystalline phase transition of memory material within the cell. Write pulse generator 102 is electrically coupled to distribution circuit 104 through signal path 110. Distribution circuit 104 is electrically coupled to memory cells 106a-106d through signal paths 112a-112d, respectively, and to sense circuit 108 through signal path 114. Each of the memory cells 106a-106d can be programmed into a memory state associated with a particular resistance value, and the resistance value is controlled using a suitable electrical write strategy.

The low temperature crystalline state has a lower electrical resistance than the amorphous state, and the high-temperature crystalline state has an electrical resistance that is lower than both the lower temperature crystalline state and the amorphous state. However, the transition of the phase change material into the higher temperature crystalline state is not desirable because large amounts of energy is required to switch the phase change material from the high temperature crystalline state back to the amorphous state. Aspects of the present invention provide a memory cell where the phase change material is suppressed from entering into the high temperature crystalline state during post-processing, or backend processing, of a semiconductor chip that includes such a memory cell.

In one embodiment, each phase-change memory cell 106a-106d includes phase-change material providing a storage location. The active region for the phase-change memory cell is where the phase-change material transitions between the crystalline state and the amorphous state for storing one bit, 1.5 bits, two bits, or several bits of data.

In one embodiment, write pulse generator 102 generates current or voltage pulses that are controllably directed to memory cells 106a-106d via distribution circuit 104. In one embodiment, distribution circuit 104 includes a plurality of transistors that controllably direct current or voltage pulses to the memory cells.

In one embodiment, memory cells 106a-106d include a phase-change material that can be changed from an amorphous state to a crystalline state, or from a crystalline state to an amorphous state, under influence of a temperature change. The degree of crystallinity defines at least two memory states useful for storing data within memory device 100. The memory state(s) can be assigned to the bit values, such as bit values “0” and “1”. The bit states of memory cells 106a-106d differ significantly in their electrical resistivity. In the amorphous state, a phase-change material exhibits significantly higher resistivity than in the crystalline state. In this manner, sense amplifier 108 reads the cell resistance such that the bit value assigned to a particular memory cell 106a-106d is determined.

To program a memory cell 106a-106d within memory device 100, write pulse generator 102 generates a current or voltage pulse for heating the phase-change material in the target memory cell. In one embodiment, write pulse generator 102 generates an appropriate current or voltage pulse, which is fed into distribution circuit 104 and distributed to the appropriate target memory cell 106a-106d. The current or voltage pulse amplitude and duration is controlled depending on whether the memory cell is being set or reset. Generally, a “set” operation of a memory cell is heating the phase-change material of the target memory cell above its crystallization temperature (but below its melting temperature) long enough to achieve the crystalline state. Generally, a “reset” operation of a memory cell is heating the phase-change material of the target memory cell above its melting temperature, and then quickly quench cooling the material, thereby achieving the amorphous state.

With regard to the transitions between the amorphous state and the crystalline states noted above, the low temperature crystalline state has a lower electrical resistance than the amorphous state, and the high-temperature crystalline state has an electrical resistance that is lower than both the lower temperature crystalline state and the amorphous state. However, it is not desirable that the phase change material occupies the high temperature crystalline state because large current is required to switch the phase change material from the high temperature crystalline state back to the amorphous state. Thus, it is desirable to structure the memory cell such that the phase change material is suppressed from entering into the high temperature crystalline state during post-processing or backend processing of a semiconductor chip including the memory cell.

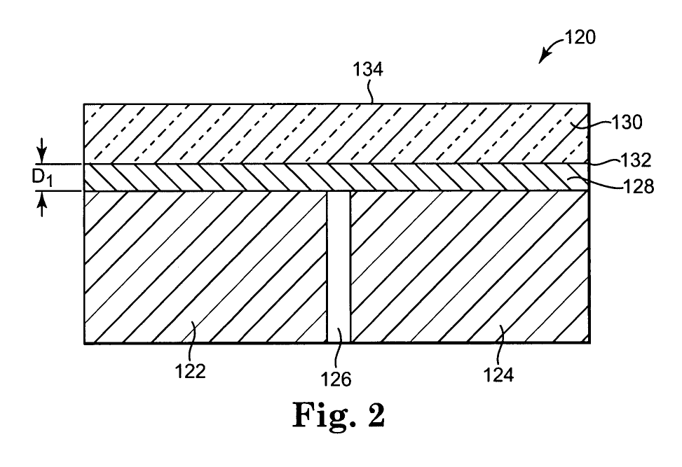

FIG. 2 illustrates a simplified cross-sectional view of a phase change memory cell 120 according to one embodiment of the present invention. Memory cell 120 includes a first electrode 122, a second electrode 124 electrically separated from the first electrode 122 by a spacer 126, a layer 128 of phase change material, and an stress layer 130 contacting the layer 128 of phase change material.

The cross-sectional view of phase change memory cell 120 is a simplified view. While FIG. 2 illustrates a bridge-type memory cell, aspects of the present invention provide for other forms of memory cells that have phase change material that is suppressed from entering into a high temperature crystalline state during post-processing. For example, the present invention provides for pillar cells and V-cell memory cells, bridge and bridged memory cells, trench memory cells, single bit cells, and other suitable forms and shapes of memory cells. It is to be understood that first electrode 122 is typically electrically connected to an active device, such as a transistor or a diode (not shown), and second electrode 124 is typically electrically connected to an upper metallization level (not shown). In one exemplary embodiment, first electrode 122 is directly coupled to a transistor and second electrode 124 is coupled to a bit line that is coupled to a sense amplifier, although other configurations are acceptable.

As illustrated in FIG. 2, layer 128 of phase change material contacts the first and second electrodes 122, 124, and stress layer 130 contacts layer 128 on a side opposite of the first and second electrodes 122, 124. Thus, in one embodiment, stress layer 130 is a top insulating layer. In another embodiment, stress layer 130 is disposed between layer 128 and the first and second electrodes 122, 124, and stress layer 130 is an under insulating layer.

Electrodes 122 and 124 electrically couple to a selection device. In one embodiment, electrodes 122, 124 are made of TiN, TaN, W, or other suitable electrode material. Spacer 126 electrically separates first electrode 122 from second electrode 124, and preferably defines a thermal conductivity that is lower than the electrodes 122, 124. For example, spacer 126 in one embodiment is made of an electrically insulating material such as SiO₂, SiN, or other electrically insulating materials.

Layer 128 contacts first electrode 122 and second electrode 124. In one embodiment, layer 128 is reversibly transitionable between an amorphous state and a low temperature crystalline state. In addition, layer 128 can be transitioned to a high temperature crystalline state. The high temperature crystalline state is also transitionable to the amorphous state, although this necessitates the application of a generally large current.

Layer 128 includes suitable phase change material(s) in accordance with the present invention. Generally, chalcogenide alloys that include one or more elements from group VI of the periodic table are useful as layer 128 materials. In one embodiment, layer 128 is made up of a chalcogenide compound material, such as GeSbTe, SbTe, GeTe, or AgInSbTe. In another embodiment, layer 128 is chalcogen free, such as GeSb, GaSb, InSb, or GeGaInSb. In other embodiments, layer 128 includes any suitable material including one or more of the elements Ge, Sb, Te, Ga, As, In, Se, and S. In addition, layer 128 may be selectively doped with nitrogen, oxygen, silicon, or another suitable material.

Layer 128 defines a dimension D₁. In one embodiment, dimension D₁ defines a film thickness of less than 50 nanometers (nm). For example, in one embodiment, spacer layer 128 is a phase change material as described above and has a dimension D₁ that is less than approximately 25 nanometers, more preferably the dimension D₁ is less than approximately 15 nanometers, and most preferably the dimension D₁ is approximately 10 nanometers.

In one embodiment, layer 128 is deposited by a process such as chemical vapor deposition (CVD), atomic layer deposition (ALD), metal organic chemical vapor deposition (MOCVD), plasma vapor deposition (PVD), jet vapor deposition (JVD), or other suitable deposition process.

Stress layer 130 contacts layer 128 at interface 132 and suppresses a transition in layer 128 to a high temperature crystalline state. For example, and with reference to stress layer 130 as a top insulating layer as illustrated in FIG. 2, when a thickness of stress layer 130 is sufficiently small enough and the stress within stress layer 130 is non-zero, effects of the stress layer 130 due to surface energy will dominate the effects due to volume energy, and stress layer 130 will operate to suppress a transition in the phase change material to the high temperature crystalline state. In one embodiment, stress layer 130 defines a thickness of between approximately 5 nm and 50 nm such that the effects of the stress layer 130 due to surface energy dominate at interface 132.

In one embodiment, the stress layer 130 is a densified layer of silicon nitride that defines a stress distribution between interface 132 and surface 134 such that the stress at interface 132 is non-zero. Stress layer 130 is, in one embodiment, an electrical insulator and preferably defines a bulk stress that is non-zero at interface 132. In one exemplary embodiment, stress layer 130 includes a densified layer of Si₃N₄ and defines a non-zero stress at interface 132 that suppresses a transition in layer 128 to a high temperature crystalline state. In another embodiment, stress layer 130 is everywhere parallel to the layer 128. In another embodiment, stress layer 130 is a shunt resistor.

In one embodiment, stress layer 130 is a multi-layered stack including at least two layers, where at least one of the layers in the multi-layered stack is a densified layer of silicon nitride that defines a stress distribution between interface 132 and surface 134 such that the stress at interface 132 is non-zero.

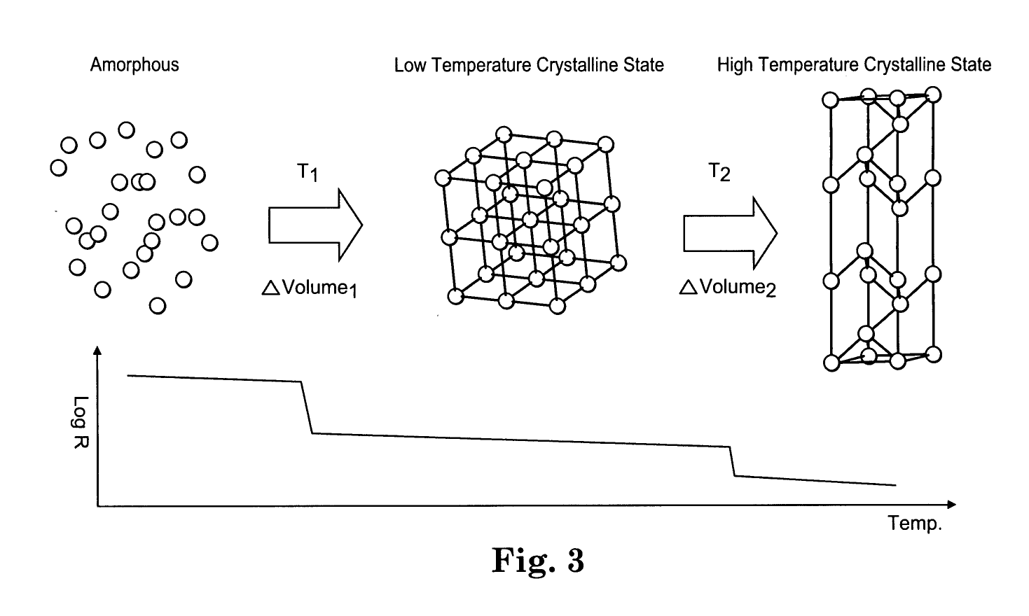

FIG. 3 illustrates a generalized schematic of a relationship between electrical resistance and temperature for one embodiment of layer 128. For descriptive clarity, the following description refers to one embodiment where layer 128 is Ge₂Sb₂Te₅, although it is to be understood that other phase change materials will have different transition temperatures and different volume changes associated with the different transition temperatures.

An amorphous state is illustrated having a generally random molecular structure associated with a generally high electrical resistance. The amorphous state is transitionable to other states, including crystalline states, and these phase transitions are associated with particular volume energies. Layer 128 transitions between phases in response to temperature changes. Some of the temperature changes are initiated by electrodes 122, 124 (FIG. 2) during storage of data in a memory state. Other temperature changes result from thermal treatment of memory cell 120 during processing, for example, backend processing of memory cell 120. Thus, the following discussion of thermal treatments is related to temperature conditions to which layer 128 is exposed to during memory storage and various processing techniques directed to memory cell 120.

For example, following a first thermal treatment T₁, layer 128 experiences a first change in volume (ΔVolume 1) and transitions from the amorphous state to a low temperature crystalline state. The low temperature crystalline state has a generally lower electrical resistance than the amorphous state. In one embodiment, the first thermal treatment T₁ is conducted at a temperature of between approximately 150 and 200 degrees Celsius, and ΔVolume 1 is a volume change of approximately −7% (i.e., an increase in molecular density associated with a 7% decrease in molecular volume relative to the amorphous state). Thus, the phase transition from the amorphous state to the low temperature crystalline state is associated with a volume energy. In one embodiment, the low temperature crystalline state is characterized by a face center cubic (FCC) molecular crystalline orientation as illustrated. In addition, layer 128 is transitionable between the low temperature crystalline state and the high temperature crystalline state, for example during semiconductor chip processing, although this transition is energetically non-desirable during an initial memory reset of memory cell 120 (FIG. 2).

A second thermal treatment T₂ is illustrated depicting a phase change material having a second change in volume (ΔVolume 2) and transitioning from the low temperature crystalline state to a high temperature crystalline state. The high temperature crystalline state has a generally lower electrical resistance than either of the amorphous state of the low temperature crystalline state. In one embodiment, the second thermal treatment T₂ is conducted at a temperature of between approximately 340 and 380 degrees Celsius, and ΔVolume 2 is a volume change of approximately −2% (i.e., an increase in molecular density associated with a 2% decrease in molecular volume relative to the amorphous state). Thus, a volume energy is associated with the T₂/ΔVolume 2 phase transition to the high temperature crystalline state. In one embodiment, the high temperature crystalline state is characterized by a hexagonal closest packed (HCP) molecular crystalline orientation as illustrated.

In general, the transition from the low temperature crystalline state to the high temperature crystalline state is not desirable. The low temperature crystalline state is beneficially employed for data storage. In contrast, the high temperature crystalline state is not beneficial for data storage, and indeed creates an unnecessary decrease in volume and decrease in electrical resistance within the layer 128. Consequently, relatively large amounts of (volume) energy are required to transition the layer 128 from the high temperature crystalline state back into the amorphous state.

Stress layer 130 defines a stress at interface 132 and a surface energy that is greater than the volume energy for the transition to the high temperature crystalline state, thereby suppressing a transition in the layer 128 to the high temperature crystalline state. While not bound by this theory, it is believed that the transition in the phase change material from the FCC molecular crystalline orientation of the low temperature crystalline state to the HCP molecular crystalline orientation of the high temperature crystalline state is shifted to higher temperatures in the presence of stress layer 130. In particular, the transition to the high temperature crystalline state is shifted to occur at temperatures above approximately 450 degrees Celsius, which is much greater than processing temperatures for exemplary Ge₂Sb₂Te₅ memory arrays, generally.

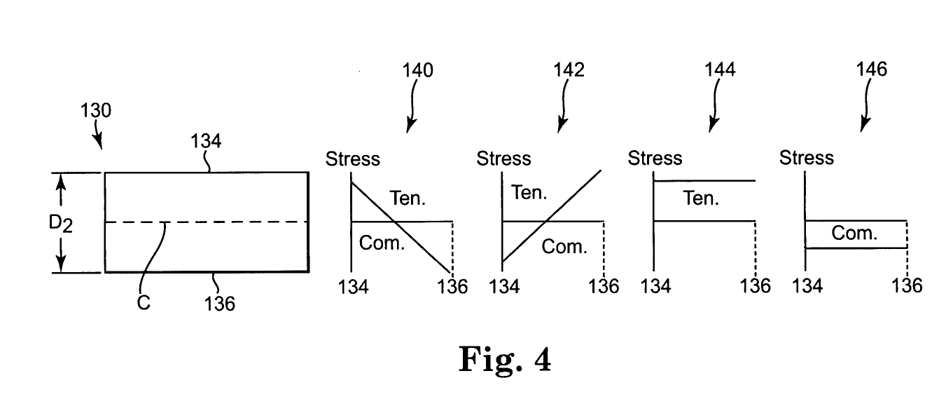

FIG. 4 illustrates stress distributions in stress layer 130 according to embodiments of the present invention. Stress layer 130 defines surface 134 and an interface surface 136. As a point of reference, interface surface 136 contacts layer 128 (FIG. 2) along interface 132. In one embodiment, surface 134 is a top surface configured for appropriate semi-conductor post-processing, and interface surface 136 is a bottom surface of stress layer 130 contacting layer 128.

The stress within stress layer 130 can be distributed in a variety of configurations, all associated with a non-zero stress at interface 132 (FIG. 2). For clarity of illustration, a centerline C is illustrated bisecting stress layer 130 at approximately a mid-point of thickness D₂. Stress distributions 140, 142, 144, and 146 illustrate stress along the abscissa as distributed between surface 134 and interface surface 136 shown along the ordinate.

Stress distribution 140 is a linear distribution of stress from surface 134 to interface surface 136. The stress at surface 134 is a tensile stress (Ten.) and the stress at the interface surface 136 is a compressive stress (Com.). In one embodiment, the compressive stress at interface surface 136 balances the tensile stress at surface 134. In one embodiment, the distribution of stress within stress layer 130 is non-linear (for example, the stress is distributed between surface 134 and interface surface 136 quadratically), although other stress distributions are acceptable. In any regard, the stress at interface surface 136 is non-zero.

Stress distribution 142 is a linear distribution of stress between surface 134 and interface surface 136, resulting in a tensile stress at interface surface 136.

In another embodiment, stress distribution 144 includes an approximately constant tensile stress (Ten.) between surface 134 and interface 136. Thus, the stress at both surface 134 and interface surface 136 is a tensile stress. As illustrated, the tensile stress distribution 144 is non-zero at interface surface 136.

In another embodiment, stress distribution 146 includes an approximately constant compressive stress (Com.) between surface 134 and interface 136. Thus, the stress at both surface 134 and interface surface 136 is a compressive stress. As illustrated, the compressive stress distribution 1446 is non-zero at interface surface 136.

Each of the stress distributions 140, 142, 144, and 146 defines a non-zero stress at interface surface 136 that is configured to suppress a transition in layer 128 to a high temperature crystalline state.

Stress layer 130 defines a thickness D₂. In one embodiment, thickness D₂ is between approximately 5-50 nanometers. Stress layer 130 (with reference to FIG. 2) is deposited in a process such as chemical vapor deposition (CVD), atomic layer deposition (ALD), metal organic chemical vapor deposition (MOCVD), plasma vapor deposition (PVD), jet vapor deposition (JVD), or other suitable deposition processes. For example, in one embodiment stress layer 130 is deposited in a CVD process as a block exposure onto layer 128 to define a thickness of dimension D₂.

In one embodiment, stress layer 130 is deposited at a rate of, for example, 1 Angstrom per second, such that the thickness D₂ is dependent upon a deposition time over which layer 130 is deposited. In this manner, stress layer 130 is deposited to have a thickness D₂ ranging between 5-50 nm.

With additional reference to FIG. 2, stress layer 130 contacts layer 128 such that an interface 132 suppresses a transition in layer 128 to the high temperature crystalline state. In this manner, during back end processing where electrodes 122 and 124 are electrically coupled to a selection device, for example a metallization device, a word line, or a bit line, etc., stress layer 130 shields and suppresses a transition in layer 128 to high temperature crystalline states that might otherwise occur during high temperature back end processing.

For example, and with reference to FIG. 3, certain processes in the back end processing of electrically connecting electrodes 122 and 124 to other devices can expose layer 128 to temperatures T₂ of about 350 degrees Celsius. Layer 128 is at risk of transitioning to the high temperature crystalline state, thus necessitating a high reset current in the memory cell 120. However, stress layer 130 has a surface energy and a stress at interface surface 136 that suppresses such a thermal transition in layer 128 to the high temperature crystalline state. Thus, during a reset of the memory for the first time, the layer 128 will reset from the low temperature crystalline state (a data storage state) back to the amorphous state, and therefore obviating the energetically undesirable transition from the high temperature crystalline state.

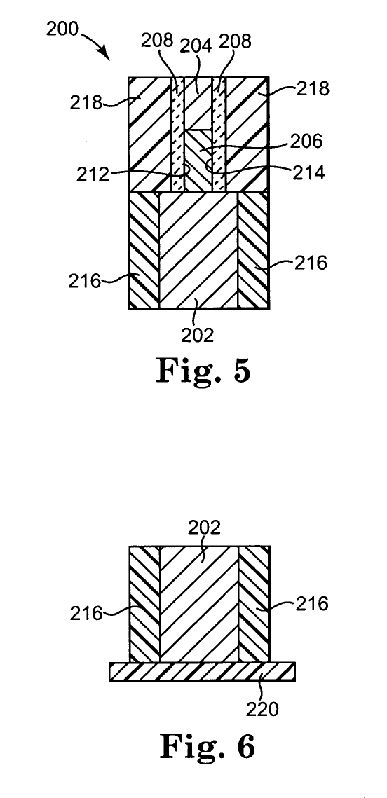

FIG. 5 illustrates a pillar phase change memory cell 200 according to one embodiment of the present invention. Pillar memory cell 200 includes a first electrode 202, a second electrode 204, a layer of phase change material disposed between and communicating with first and second electrodes 202, 204, and a stress layer 208 in contact with the layer 206 of phase change material. Stress layer 208 contacts layer 206 along interface 212 and interface 214. As described above, stress layer 208 defines interfaces 212, 214, respectively, that operate to suppress a transition in layer 206 of phase change material to a high temperature crystalline state.

In one embodiment, insulation material 216 insulates first electrode 202, and insulation material 218 insulates second electrode 204.

In one embodiment, electrode 202 is a bottom electrode, and electrode 204 is a top electrode. Electrodes 202, 204 can be deposited as layers by employing any one of a variety of deposition techniques, as described above. In one embodiment, electrodes 202, 204 include metal nitride materials, such as titanium nitride, titanium silicon, titanium aluminum nitride, or tungsten nitride/titanium tungsten materials.

In one embodiment, memory cell 200 is formed as part of a selection device (not shown) and is selectively formed between a contact plug and a contact pad (neither shown) of the selection device.

FIGS. 6-13 illustrate cross-sectional views of various stages of fabrication of pillar memory cell 200. To simplify the description, the various processes will be described for the specific embodiment illustrated in FIG. 5, but one skilled in the art will understand how other alternative embodiments may be similarly fabricated.

In addition, although formation of a single memory cell is illustrated in the figures, one skilled in the art will recognize that a typical fabrication process will involve fabrication of multiple memory cells. It is assumed that each of these memory cells includes a phase change material and is operable with a selection device. However, to simplify the illustration and description of FIGS. 6-13, the selection device and associated plate lines will not be illustrated.

FIG. 6 illustrates first electrode 202 deposited onto a substrate 220 according to one embodiment of the present invention. In one embodiment, substrate 220 forms a portion of a selection device that includes a field effect transistor including a source and a drain and a control gate (none of which is illustrated). In an other embodiment, substrate 220 forms a portion of a selection device that includes a bipolar transistor (none of which is illustrated). In an other embodiment, substrate 220 forms a portion of a selection device that includes a diode (none of which is illustrated). In any regard, electrode 202 is deposited on substrate 220 in a suitable deposition process. Suitable deposition processes include: a CVD process, an ALD process, a MOCVD process, a PVD process, or a JVD process, or other suitable deposition process, as described above. In a similar manner, insulator 216 is deposited around electrode 202 to electrically insulate electrode 202.

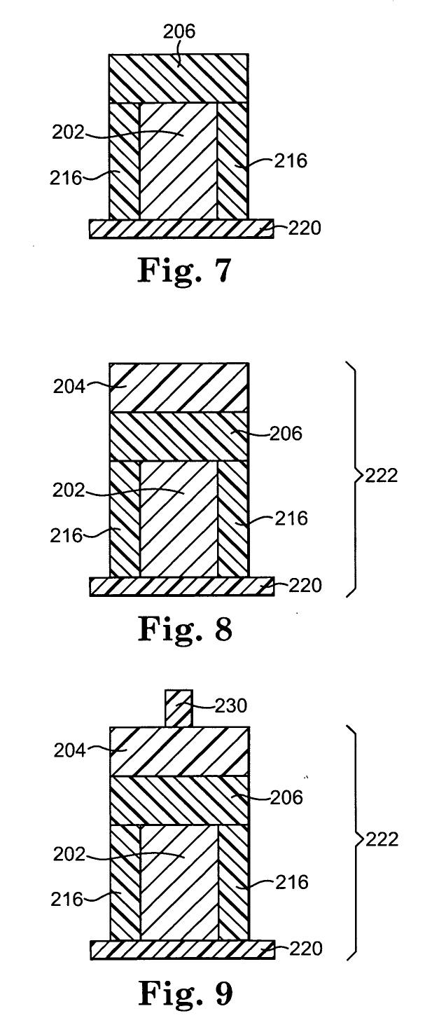

FIG. 7 illustrates layer 206 of phase change material disposed on electrode 202.

FIG. 8 illustrates a stack 222 including second electrode 204 disposed upon layer 206 of phase change material according to one embodiment of the present invention. Stack 222 includes first electrode 202, layer 206, and second electrode 204. As described above, in one embodiment electrode 202 is a bottom electrode, and electrode 204 is a top electrode.

FIG. 9 illustrates a photoresist 230 disposed on second electrode 204 of stack 222 according to one embodiment of the present invention.

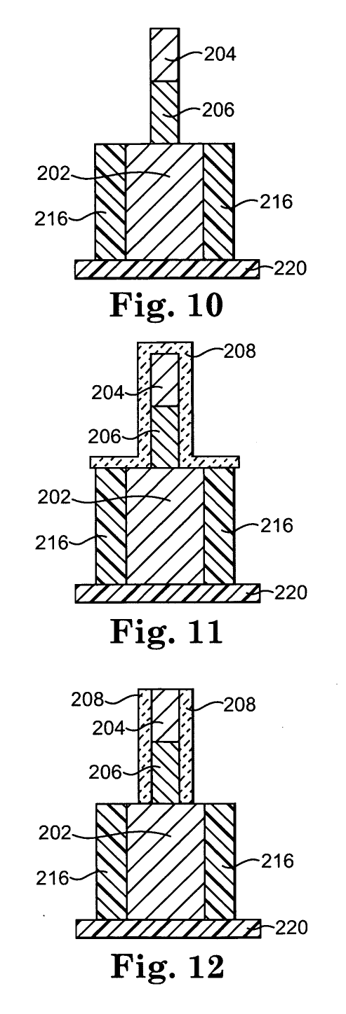

FIG. 10 illustrates stack 222 after etch and strip processes according to one embodiment of the present invention. Photoresist 230 (FIG. 9) is in one embodiment a negative photoresist. Negative photoresist 230 is lithographically processed, where stack 222 is exposed to an energy source, such as UV light, for example. Thereafter, non-reacted portions around of photoresist 230 are washed away, leaving a pillar of electrode 204 and layer 206. FIG. 10 illustrates stack 222 after layer 206 and electrode 204 have been etched, and photoresist 230 has been stripped away, to define a pillar of layer 206 of phase change material between electrodes 202 and 204.

FIG. 11 illustrates a stress layer 208 contacting etched layer 206 of phase change material according to one embodiment of the present invention. In one embodiment, and as illustrated in FIG. 11, stress layer 208 contacts second electrode 204 and layer 206 and overlaps insulator 216.

FIG. 12 illustrates stress layer 208 etched back to define columns of vertically aligned stress layers contacting layer 206 of phase change material according to one embodiment of the present invention. In particular, FIG. 12 illustrates stress layer 208 etched back off of insulators 216.

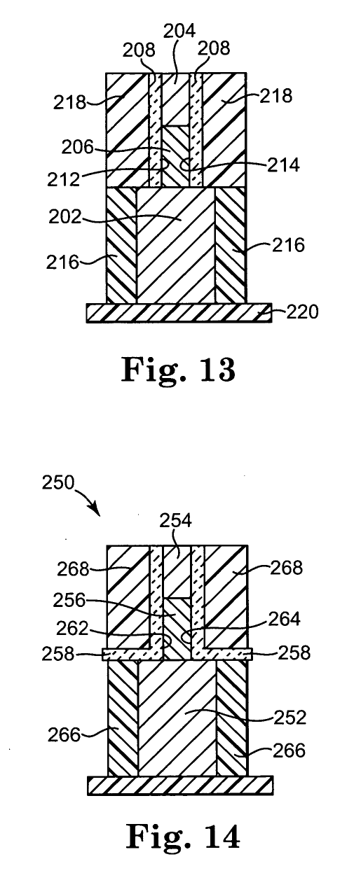

FIG. 13 illustrates insulation layer 218 disposed and in contact with stress layer 208 after a planarization process according to one embodiment of the present invention. The planarization process in one embodiment includes a chemical mechanical planarization (CMP process), although suitable planarization processes are also acceptable. Stress layer 208 contacts layer 206 of phase change material along at least two interfaces (interfaces 212 and 214, for example), and operates to suppress a transition in the phase change material to a high temperature crystalline state.

FIG. 14 illustrates another pillar phase change memory cell 250 according to one embodiment of the present invention. Pillar memory cell 250 includes a first electrode 252, a second electrode 254 electrically separated from first electrode 252, and a layer 256 of phase change material communicating with first and second electrodes 252, 254. A stress layer 258 contacts layer 256 of phase change material. In one embodiment, stress layer 258 has not been etched back and separates a first insulator 266 from a second insulator 268. Stress layer 258 contacts layer 256 of phase change material and defines a first interface 262 and a second interface 264, where the interfaces 262, 264 operate to suppress a transition in the phase change material to a high temperature crystalline state.

A stress layer defining a stress at an interface of a layer of phase change material, and a surface energy that is greater than the volume energy for the transition to the high temperature crystalline state in the phase change material, has been described that suppresses a transition in the layer of phase change memory material to the high temperature crystalline state(s).

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory cell comprising:
a first electrode;
a second electrode;
a layer of phase change material positioned between the first and second electrodes, the phase change material including a high temperature state; and
a stress layer contacting the layer of phase change material, wherein the stress layer defines an interface with the phase change material and operates to suppress a transition in the phase change material to the high temperature state.

2. The memory cell of claim 1, wherein the stress layer contacts the layer of phase change material on a side opposite the first and second electrodes.

3. The memory cell of claim 1, wherein the stress layer is disposed between the layer of phase change material and the first and second electrodes.

4. The memory cell of claim 1, wherein the stress layer defines a thickness of between approximately 5 nm and 50 nm.

5. The memory cell of claim 1, wherein the stress layer comprises Si₃N₄ and defines a stress at the interface that is non-zero.

6. A memory cell comprising:
a first electrode;
a second electrode electrically separated from the first electrode;
a layer of phase change material communicating with the first and second electrodes and transitionable between an amorphous state and a low temperature crystalline state, the phase change material including a high temperature crystalline state; and
a stress layer contacting the layer of phase change material, wherein the stress layer defines an interface with the phase change material and operates to suppress a transition in the phase change material to the high temperature crystalline state.

7. The memory cell of claim 6, wherein the stress layer contacts the layer of phase change material on a side opposite the first and second electrodes.

8. The memory cell of claim 6, wherein the stress layer is disposed between the layer of phase change material and the first and second electrodes.

9. The memory cell of claim 6, wherein the stress layer defines a thickness of between approximately 5 nm and 50 nm.

10. The memory cell of claim 6, wherein the layer of phase change material defines a thickness of between approximately 5 nm and 100 nm.

11. The memory cell of claim 6, wherein the layer of phase change material comprises at least one of Ge, Sb, Te, Ga, As, In, Se, and S.

12. The memory cell of claim 6, wherein the stress layer is a densified layer of Si₃N₄ defining a stress distribution through the layer such that a stress at the interface is non-zero.

13. The memory cell of claim 12, wherein the stress at the interface is a compressive stress.

14. The memory cell of claim 6, wherein the phase change material defines a substantially planar layer such that the interface between the stress layer and the phase change material is substantially planar and parallel to the layer of phase change material.

15. The memory cell of claim 6, wherein the layer of phase change material is reversibly transitionable between the amorphous state and one low temperature crystalline state.

16. The memory cell of claim 6, wherein the stress layer comprises multiple layers.

17. The memory cell of claim 6, wherein the stress layer is a shunt resistor.

18. A memory device comprising:
a distribution circuit;
a write pulse generator electrically coupled to the distribution circuit;
a sense circuit electrically coupled to the distribution circuit and electrically coupled to the write pulse generator through a signal path; and
an array of memory cells electrically coupled to the distribution circuit, each memory cell comprising:
a first electrode,
a second electrode separated from the first electrode,
a layer of phase change material contacting the first and second electrodes that is reversibly transitionable between an amorphous state and a low temperature crystalline state, the phase change material including a high temperature crystalline state, and a stress layer contacting the phase change material;
wherein the stress layer operates to suppress a transition in the phase change material to the high temperature crystalline state.

19. The memory device of claim 18, wherein the stress layer defines a thickness of between approximately 5 nm and 50 nm.

20. The memory device of claim 18, wherein the stress layer is a densified layer of Si₃N₄.

21. The memory device of claim 18, wherein the stress layer defines a planar interface with the layer of phase change material.

22. A memory cell comprising:
a first electrode;
a second electrode separated from the first electrode;
a layer of phase change material contacting the first and second electrodes that is reversibly transitionable between an amorphous state and a low temperature crystalline state, the phase change material including a high temperature crystalline state; and
means for suppressing a transition in the phase change material to the high temperature crystalline state.

23. The memory cell of claim 22, wherein the layer of phase change material defines a planar surface opposite the first and second electrodes, and further wherein the means for suppressing a transition in the phase change material to the high temperature crystalline state comprises a stress layer defining an interface at the planar surface.

24. The memory cell of claim 23, wherein the stress layer is parallel to the phase change material.

25. The memory cell of claim 22, wherein the means for suppressing a transition in the phase change material to the high temperature crystalline state comprises a stress layer defining an interface with the phase change material having a non-zero stress configured to suppress a transition in the phase change material from a face centered cubic crystal orientation to a hexagonal closest packed crystal orientation.

26. The memory cell of claim 22, wherein the means for suppressing a transition in the phase change material to the high temperature crystalline state comprises a stress layer defining a film thickness of less than 50 nm contacting the layer of phase change material.

27. A method of controlling a memory state in a memory cell comprising:
providing a memory cell with a phase change material transitionable between an amorphous state and a low temperature crystalline state and a stress layer in contact with the phase change material;
electrically connecting the memory cell to a memory device; and
preventing the phase change material from orienting in a high temperature crystalline state.

28. The method of claim 27, wherein preventing the phase change material from orienting in a high temperature crystalline state comprises preventing the phase change material from orienting in a hexagonal closest packed crystalline orientation.

29. The method of claim 27, wherein preventing the phase change material from orienting in a high temperature crystalline state comprises providing a surface energy in the stress layer that exceeds a volume energy for a phase transition to the high temperature crystalline state in the phase change material.

30. The method of claim 27, wherein the stress layer is a densified layer of Si₃N₄ defining a stress distribution through the layer such that a stress at an interface between the phase change material and the stress layer is non-zero.

31. The method of claim 27, wherein the stress layer defines a linear stress distribution through a thickness of the stress layer.

32. A method of forming a phase change memory cell reversibly transitionable between an amorphous state and a low temperature crystalline state, the method comprising:
providing a layer of phase change material contacting first and second electrodes;
depositing a stress layer onto the layer of phase change material; and
backend processing the memory cell at a temperature above the low temperature crystalline state;
wherein the stress layer impedes a transition in the phase change material to a high temperature crystalline state.

33. The method of claim 32, wherein depositing a stress layer onto the layer of phase change material comprises block deposition a stress layer having a sub-lithographic thickness of between approximately 40 nm and 70 nm.

34. The method of claim 32, wherein depositing a stress layer onto the layer of phase change material forms an interface between the stress layer and the phase change material, the interface defining a non-zero stress.

35. The method of claim 32, wherein the stress layer defines a linear stress distribution through a thickness of the stress layer.

36. The method of claim 32, wherein depositing a stress layer onto the layer of phase change material comprises depositing a parallel stress layer onto the phase change material.
